(19) United States
(12) Patent Application Publication
(10) Pub. No.: US 2009/0166722 A1
(43) Pub. Date: Jul. 2, 2009

(54) High voltage structures and methods for vertical power devices with improved manufacturability

(75) Inventor: Francois Hebert, San Mateo, CA (US)

Correspondence Address: BO-IN LIN, 13445 MANDOLI DRIVE, LOS ALTOS HILLS, CA, 94022, US

(73) Assignee: Alpha & Omega Semiconductor, LTD:

(21) Appl. No.: 12/005,878

(22) Filed: Dec. 28, 2007

(51) Int. Cl. H01L 29/78; H01L 21/336

(52) U.S. Cl. 257/328; 438/268; 257/E29.257; 257/E21.41

(57) ABSTRACT

This invention discloses a semiconductor power device disposed on a semiconductor substrate supporting an epitaxial layer as a drift region composed of an epitaxial layer. The semiconductor power device further includes a super-junction structure includes a plurality of doped sidewall columns disposed in a multiple of epitaxial layers. The epitaxial layer have a plurality of trenches opened and filled with the multiple epitaxial layer therein with the doped columns disposed along sidewalls of the trenches disposed in the multiple of epitaxial layers.

### BACKGROUND OF THE INVENTION

1. Field of the Invention

The invention relates generally to the vertical semiconductor power devices. More particularly, this invention relates to configurations and methods with improved manufacturability for manufacturing vertical semiconductor power devices with a super-junction structure for high voltage applications.

2. Description of the Prior Art

Conventional manufacturing technologies and device configuration to further increase the breakdown voltage with reduced series resistance are still confronted with manufacturability difficulties. The practical applications and usefulness of the high voltage semiconductor power devices are limited due to the facts that the conventional high power devices generally have structural features that require numerous time-consuming, complex, and expensive manufacturing processes. Some of the processes for manufacturing the high voltage power devices have low throughput and low yields. Specifically, multiple epitaxial layers and buried layers are required in some of the conventional structures and some devices require very deep trenches, which require a long time to etch. Multiple etch back and chemical mechanical polishing (CPM) processes are necessary in most of the device structures according to the manufacturing processes disclosed so far. Furthermore, the manufacturing processes often require equipment not compatible with standard foundry processes. For example, many standard high-volume semiconductor foundries have oxide CMP (chemical mechanical polishing) but do not have silicon CMP, which is required for some superjunction approaches. Additionally, these devices have structural features and manufacturing processes not conducive to scalability for low to high voltage applications. In other words, some approaches would become too costly and/or too lengthy to be applied to higher voltage ratings. As will be further reviewed and discussions below, these conventional devices with different structural features and manufactured by various processing methods, each has limitations and difficulties that hinder practical applications of these devices as now demanded in the marketplace.

There are three basic types of semiconductor power device structures for high voltage applications. The first type includes those device formed with standard structures as depicted in FIG. 1A for a standard VDMOS that do not incorporate functional feature of charge balance. For this reason, there is no breakdown voltage enhancement beyond the one-dimensional theoretical figure of merit, i.e., the Johnson limit, according to the I-V performance measurements and further confirmed by simulation analyses of this type of devices. The devices with this structure generally have s relatively high on-resistance due to the low drain drift region doping concentration in order to satisfy the high breakdown voltage requirement. In order to reduce the resistance Rdson, this type of devices generally requires large die size. Despite the advantages that the devices can be manufactured with simple processes and low manufacturing cost, these devices are however not feasible for high current low resistance applications in the standard packages due the above discussed drawbacks: the die cost becomes prohibitive (because there are too few dies per wafer) and it becomes impossible to fit the larger die in the standard accepted packages.

The second type of devices includes structures provided with two-dimensional charge balance to achieve a breakdown voltage higher that the Johnson limit. This type of device structure is generally referred to as devices implemented with the super junction technology. In the super junction structure, a charge-balance along a direction perpendicular to the cathode plane along a direction parallel to the current flow in the drift drain region of a vertical device, e.g., a drain or collector plane, based on PN junctions such as CoolMOS™ structures by Infineon, and field plate techniques implemented in oxide bypassed devices to enable a device to achieve a higher breakdown voltage. The third type of structure involves a three-dimensional charge-balance where the coupling is both in the lateral as well as the vertical directions. Since the purpose of this invention is to improve the structural configurations and manufacturing processes of devices implemented with super junction technologies to achieve two-dimensional charge balance, the limitations and difficulties of devices with super junction will be reviewed and discussed below.

FIG. 1B is a cross sectional view of a device with super junction to reduce the specific resistance (Rsp, resistance times active area) of the device by increasing the drain dopant concentration while maintaining the specified breakdown voltage. The charge balance is achieved by providing P-type vertical columns formed in the drain to result in lateral and complete depletion of the drain at high voltage thus pinch off and shield the channel from the high voltage drain at the N+ substrate. Such technologies have been disclosed in Europe Patent 0053854 (1982), U.S. Pat. No. 4,754,310, specifically in FIG. 13 of that Patent and U.S. Pat. No. 5,216,275. In these previous disclosures, the vertical super junctions are formed as vertical columns of N and P types dopant. In vertical DMOS devices, the vertical charge balance is achieved by a structure with sidewall doping to form one of the doped columns as were illustrated in drawings. In addition to doped columns, doped floating islands have been implemented to increase the breakdown voltage or to reduce the resistance as disclosed by U.S. Pat. No. 4,134,123 and U.S. Pat. No. 6,037,632. Such device structure of super junction still relies on the depletion of the P-regions to shield the gate/channel from the drain. The floating island structure is limited by the technical difficulties due to charge storage and switching issues.

The conventional device structures of class-one type devices as discussed above still have limitations that such devices require die of large size to achieve a low Rdson resistance. Due to the size issue, it is usually not feasible to achieve low Rdson and high current application by using standard power packages. For class-two and class-three types of devices, the manufacture methods are generally very complex, expensive and require long processing time due to the facts that the methods require multiple steps and several of these steps are slow and having a low throughput. Specifically, the steps may involve multiple epitaxial layers and buried layers. Some of the structures require deep trenches through the entire drift region and require etch back or chemical mechanical polishing in most these processes. For these reasons, the conventional structures and manufacture methods are limited by slow and expensive manufacturing processes and are not economical for broad applications.

Therefore, a need still exists in the art of power semiconductor device design and manufacture to provide new device configurations and manufacturing method in forming the power devices such that the above discussed problems and limitations can be resolved.

### SUMMARY OF THE PRESENT INVENTION

It is therefore an aspect of the present invention to provide a new and improved device structure and manufacturing method to form the doped columns in the drift regions for charge balance with simple and convenient processing steps achieved through doping trench sidewalls of deep trenches that do not extend through the entire vertical drift region. There are no etch-back or CMP (chemical mechanical polishing) required thus reducing the processing steps and can be implemented with just few and thin epitaxial growth such as two epitaxial layers less than fifteen micrometers thickness for each layer. The manufacturing processes required a few staged trenches with reasonable aspect ratio, e.g., two staged trenches less than 15 microns with aspect ratio of approximately 5:1. The device can be conveniently manufactured with standard processing using standard processing modules and equipment. Therefore, the above discussed technical difficulties and limitations can be resolved.

Specifically, it is an aspect of the present invention to provide a new and improved device structure and manufacturing method to form the doped columns in the drift regions for charge balance achieved through doping trench sidewalls of deep trenches that do not extend through the entire vertical drift region and connected through the body region with a buried linker region. Furthermore, the doped columns, e.g., the P-doped columns are connected to the body regions at distributed locations within the active regions. This new configuration enables the current to flow on both sides of the narrow P-columns to enhance the device performance.

It is another aspect of the present invention to provide a new and improved device structure and manufacturing method to form the doped columns in the drift regions for charge balance achieved through doping trench sidewalls of deep trenches with simplified, convenient and scalable processing steps. The number of epitaxial layers can be increased to three layers with three trench opening processes having reduced trench depth of less than ten microns and reduced epitaxial layer thickness of less than ten microns. Broader and economical applications of such device are therefore practical with improved device performances.

It is another aspect of the present invention to provide new and improved device structure and manufacturing method to form the doped columns in the drift regions for charge balance that requires small number epitaxial growth with relative small thickness. The production costs for such devices are therefore significantly reduced.

It is another aspect of the present invention to provide new and improved device structure and manufacturing method to form the doped columns in the drift regions for charge balance by forming narrow and tall doped columns in the vertical drift regions. The process involves the doping of the trench sidewalls of buried trenches. The buried trenches are opened into epitaxial layer and then refilled with epitaxial growth after ion implantations. The breakdown voltage is significantly increased while the device resistance can be favorably improved.

It is another aspect of the present invention to provide new and improved device structure and manufacturing method to form the doped columns in the drift regions for charge balance wherein the manufacturing processes do not require etch back or CMP processes to planarized the deep trenches after the trenches are filled. The throughput of these devices is improved with better product yields. The implementation cost of these devices is therefore reduced.

Briefly in a preferred embodiment this invention discloses a semiconductor power device disposed on a semiconductor substrate supporting an epitaxial layer as a drift region. The semiconductor power device further includes a super-junction structure includes a plurality of doped sidewall columns disposed in a multiple of epitaxial layers. The epitaxial layers have a plurality of trenches opened and filled therein with the epitaxial layer with the doped sidewall columns disposed along sidewalls of the trenches opened and then filled in the multiple of epitaxial layers. In a preferred embodiment, the semiconductor power device further includes a trench-bottom doped region disposed in the drift region below and linking between two of the doped sidewall columns. In another preferred embodiment, the semiconductor power device further includes a buried linker region disposed on a top epitaxial layer among the plurality of epitaxial layers for electrically linking the doped sidewall columns to an electrical terminal of the semiconductor power device.

Furthermore, this invention discloses a method of manufacturing a semiconductor power device on a semiconductor substrate supporting a drift region composed of an epitaxial layer. The method includes a step of opening a plurality of lower trenches in the drift region followed by doping sidewalls of the lower trenches to form a plurality of lower doped-sidewall columns along the sidewalls of the lower trenches. The method further includes a step of filling and covering the lower trenches with a first epitaxial layer on top of the drift region followed by opening a plurality of upper trenches substantially on top of each of the lower trenches and doping sidewalls of the upper trenches to form a plurality of upper doped-sidewall columns. The method further includes a step of filling and covering the upper trenches with a second epitaxial layer on top of the first epitaxial layer followed by applying a power device manufacturing step for extending and connecting the lower and upper doped sidewall columns into a plurality of combined doped sidewall columns in the semiconductor substrate.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A to 1B are cross sectional views for showing conventional vertical power device configurations manufactured by conventional methods.

FIGS. 2 to 9 are cross sectional views of high voltage power devices with super junction structure as different embodiments of this invention.

FIGS. 10A to 10M are a cross sectional views to illustrate processing steps of this invention to manufacture high voltage power device of FIG. 2 with super junction structures.

FIGS. 11A to 11M are a cross sectional views to illustrate processing steps of this invention to manufacture high voltage power device of FIG. 3 with super junction structures.

FIGS. 12 to 14C are cross sectional views for depicting processing steps to manufacture different high voltage power devices as shown in FIGS. 4 to 9.

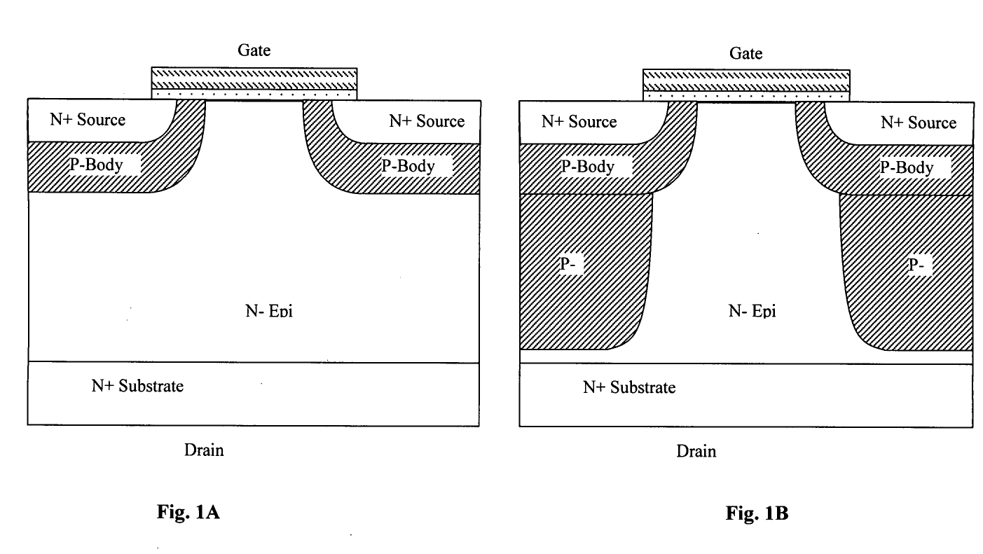

### DETAILED DESCRIPTION OF THE METHOD

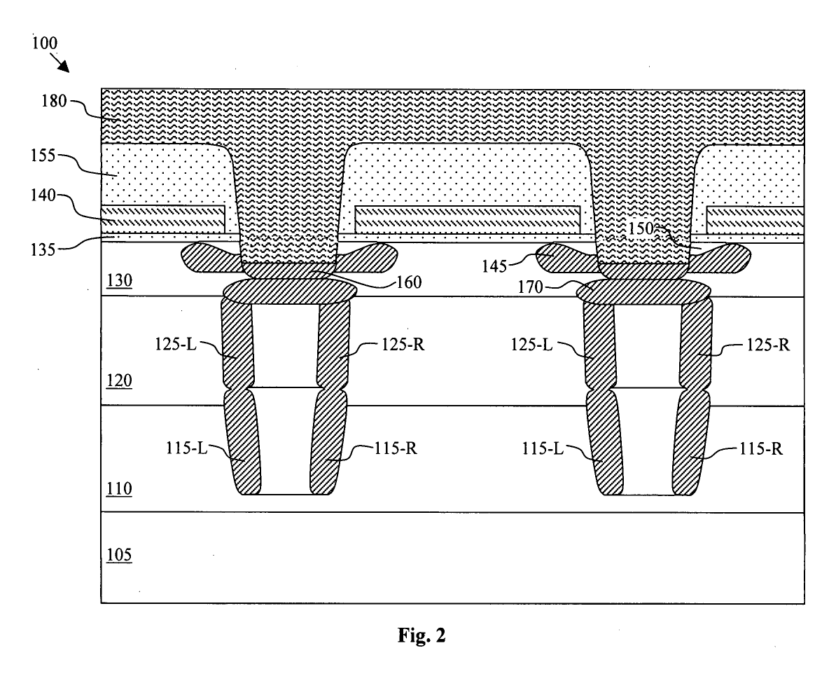

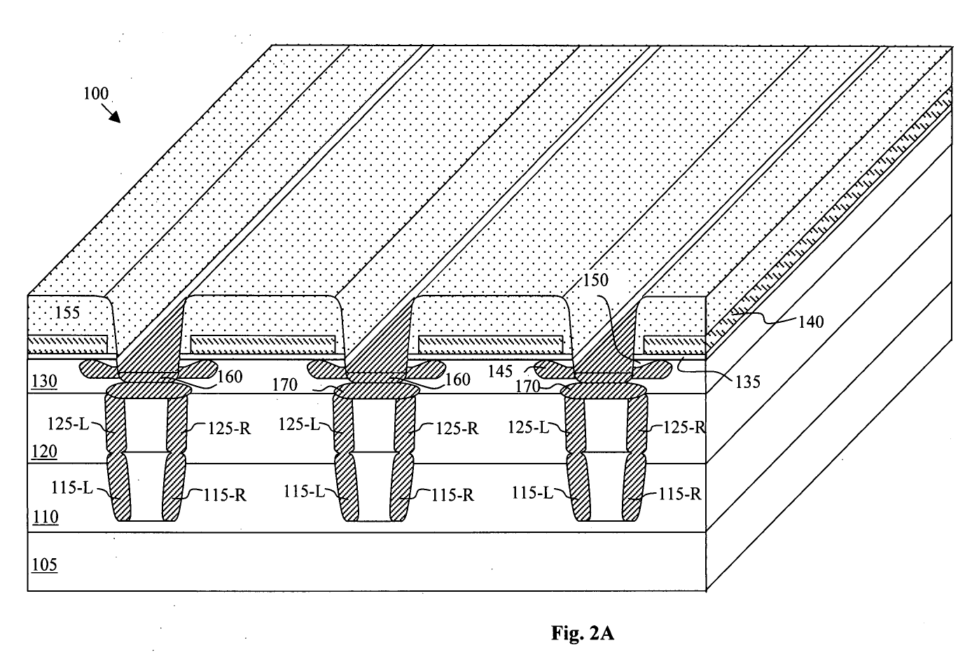

Referring to FIG. 2 for a cross sectional view of a planar MOSFET device 100 of this invention. The MOSFET device 100 is supported on an N+ silicon substrate 105 functioning as a drain terminal or electrode on a bottom surface of the substrate. The N+ substrate 105 supports a N-drift region 110 formed immediately on top of the N+ drain region 105 with a first N-epitaxial layer 120 on top of the drift region 110 and a second N-epitaxial layer 130 formed on top of the first N-epitaxial layer 120. The N-drift layer 110 includes bottom P-doped columns 115 and the first N-epitaxial layer 120 includes top P-doped columns 125. As will be further described below, the bottom P-doped columns 115 are formed by applying tilt angle P-dopant ion implantation through the sidewalls the trenches opened between two adjacent P-doped columns 115-L and 115-R. In this embodiment, compensation implant in the form of a zero tilt N-type implant (Phosphorus for example) is performed to compensate any of the P-doped column implant which may reach the flat bottom portion of the first P-doped column region.

Furthermore, by applying tilt angle P-doped implantation through the sidewalls of the trenches opened between to adjacent P-doped columns 125-R and 125-L forms the top P-doped columns. Again, compensation implants in the form of zero tilt N-type implants can be done to compensate any of the P-doped column implant which may have reached the flat transition region between the first N-epi 110 and the lower portion of the P-doped columns 125-L and 125-R.

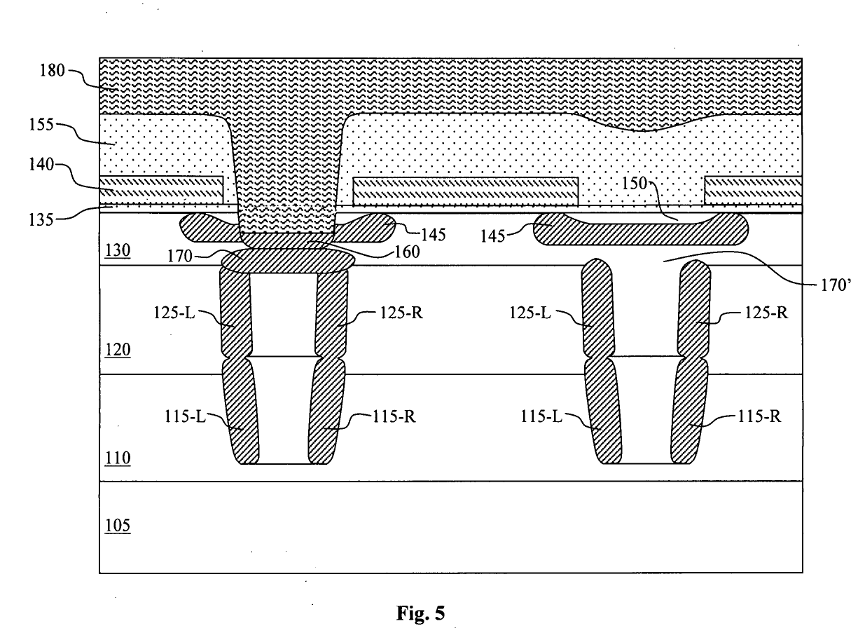

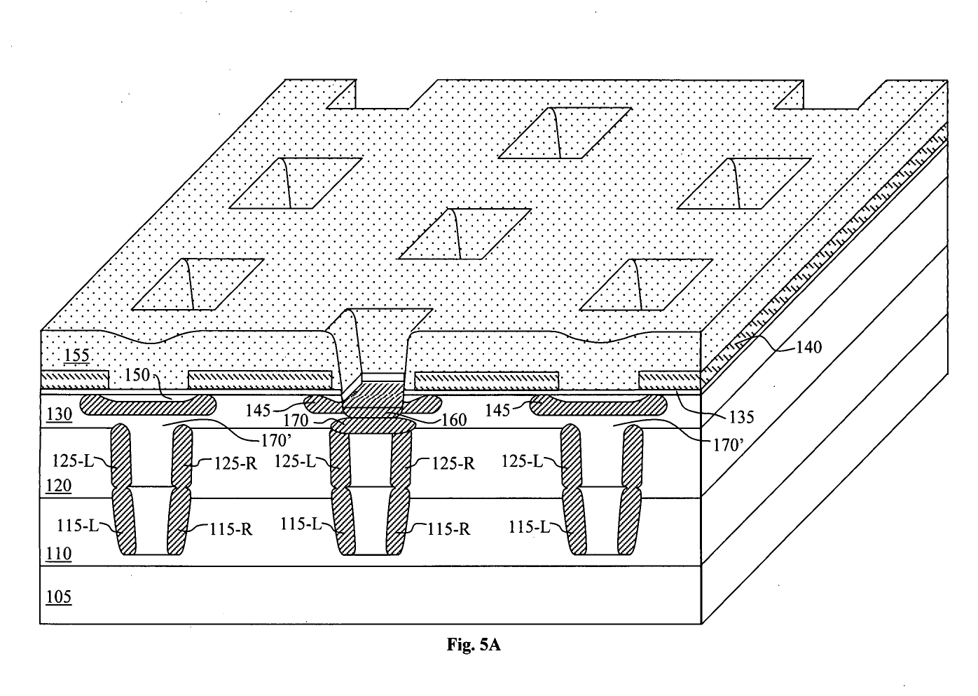

On top of two adjacent top P-doped columns 125-L and 125-R is a buried P-doped link region 170 electrically interconnects the top P-doped columns to the P-doped body contact region 160 and the two adjacent top P-doped columns 125-L and 125-R. The P-doped body contact regions 160 are disposed between two adjacent body regions 145 underneath the gate oxide layer 135 underneath the gate 140 and encompassing the source regions 150 immediately below the gate oxide layer 135, on each side of the gate electrode 140. The planar MOSFET power device comprising the gate 140 disposed over the channel region above and on each side of the source region 150 encompassed by the body regions 145 underneath the gate oxide layer 135. The semiconductor power device is covered by an oxide layer 155 with contact openings for providing metal contact layer 180 to contact the source 150 and body 145 through contact implant regions 160. Super junctions may be configured with the P regions 115 and 125 tied to the body regions 145 over the entire length of the fingers in a stripe configuration as shown in FIG. 2A As illustrated in these stripe layout configurations of FIGS. 2A and 5A, the buried linker region 170 is extended to locations where the body contact regions 160 form. In some of the embodiments, as shown in these perspective illustrations, the body contact may cover all the body regions and also, there can be embodiments, where the body contacts are distributed over portions of the body regions. Closed-cell structures are of course also possible but not shown

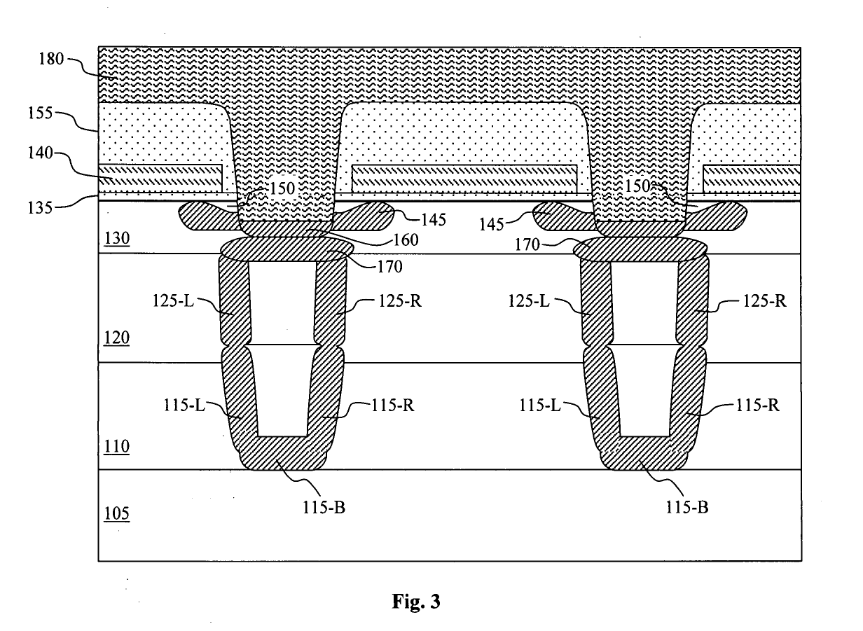

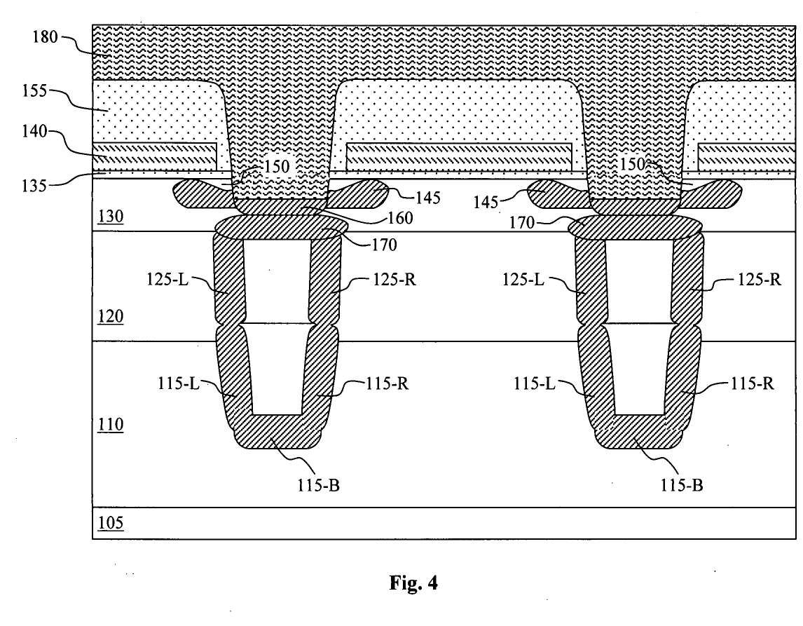

FIG. 3 is a cross sectional view of an alternate exemplary embodiment similar to the semiconductor power device 100 of FIG. 2 except that the first N-type compensating implant mentioned above, are eliminated at the trench bottom doped region 115-B below the trenches opened between adjacent P-doped columns 115-L and 115-R. FIG. 4 is a cross sectional view of another exemplary embodiment similar to the device shown in FIG. 3. The only difference is that the trench bottom P-doped regions 115-B are formed at a distance above the N+ substrate region 105. This is achieved either by using a thicker N-drift region 110, or by using a shallower first trench 115.

Among these embodiments shown in FIGS. 2 to FIG. 4, it is to be noted that a compensation implant may be required when a relative small tilt angle of 7-degrees is applied for P-sidewalls implantations. The small angle implantation may cause some of the implant ions to project into the epitaxial regions below the trench bottoms. Compensation of this P-type region is achieved by an N-type implant through the trench bottoms. However, if the tilt angle is accurately controlled, it may be feasible to implant the sidewalls only without requiring a trench bottom compensation implant through the deep trenches. In the embodiments shown in FIGS. 3 and 4, since there is an additional zero-tilt boron implant to form the trench bottom P-regions 115-B, a trench-bottom compensation implant is no longer necessary.

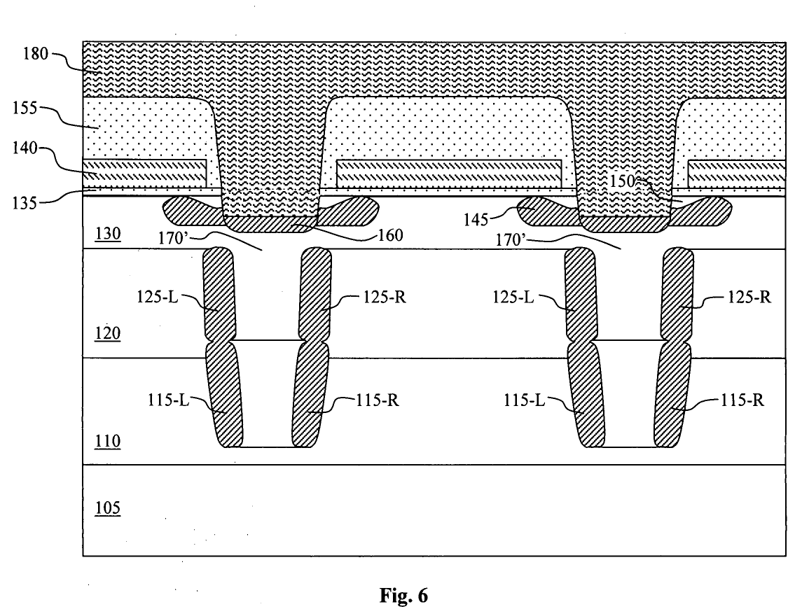

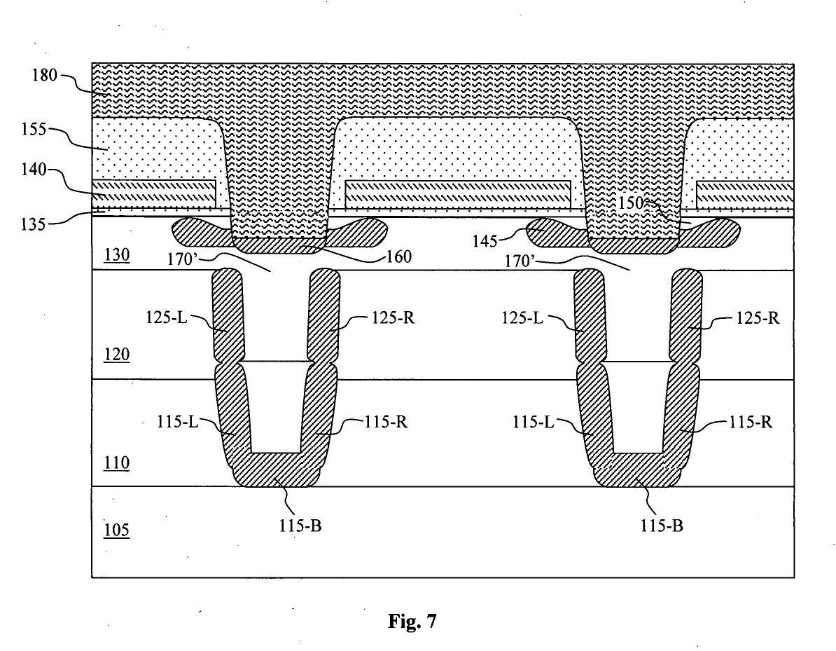

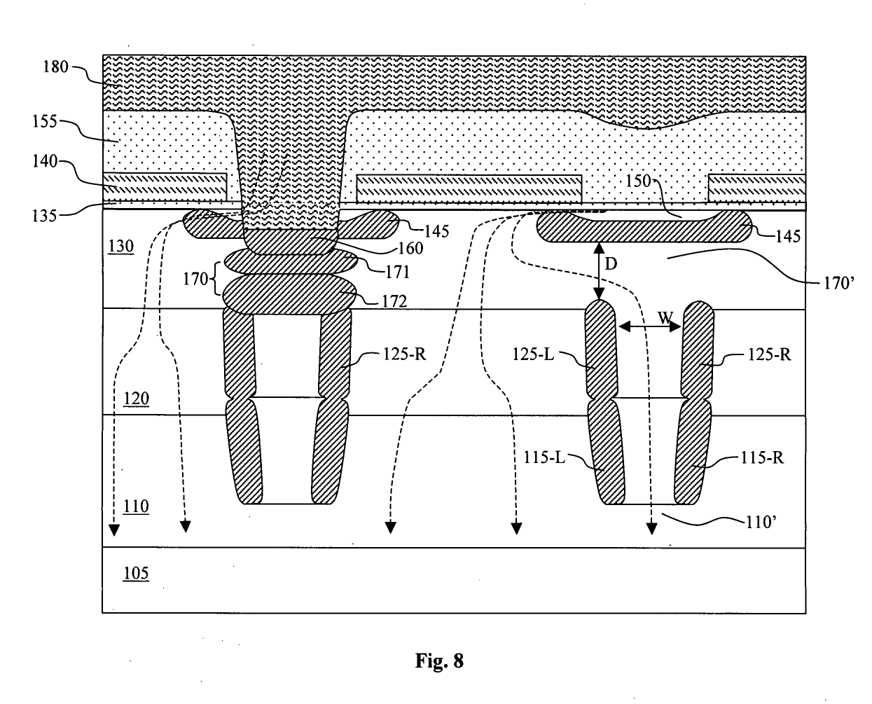

FIG. 5 is a cross sectional view of another exemplary embodiment of a semiconductor power device similar to that of FIG. 2. The only difference is that the body contacts do not open all the way along the stripe but instead only open alternatively along the stripe for metal at specific locations as illustrated in FIG. 5A. In regions 170′, there are no direct contact to the body and source regions, P-doped columns 115 and 125 are not tied to the body region but let unconnected locally, although regions 115 and 125 remain biased to the body by the body contact regions 160. FIG. 6 is a cross sectional view of another exemplary embodiment similar to the power device shown in FIG. 2 except that there are no P-doped link regions 170 and the P-doped columns 115 and 125 are formed as floating regions not connecting to the body regions. FIG. 7 is a cross sectional view of an alternate exemplary embodiment of a semiconductor power device similar to the device shown in FIG. 6. The only difference is the bottom P-doped regions 115-B at the trench bottoms below two adjacent P-doped columns 115-L and 115-R. This can be achieved by using a thicker N-drift region 110 or a shallower trench region 115. FIG. 8 is a cross sectional view of another exemplary embodiment of a semiconductor power device similar to that shown in FIG. 5. The power device has a structural configuration with distributed body to P-column contact with the P-column link regions 170 formed in selected locations. The differences between this embodiment and FIG. 5 are: thicker top epi layer 140, deeper link region 170 using multiple ion implants with higher implant energies in selected locations. In FIG. 8, link region 170 is formed using two separate ion implanted regions 171 and 172. In this power device embodiment, electric currents flow through both sides of the P-doped columns 115-L and 115-R by appropriate cell pitch and top epitaxial 145 thickness selection. This is possible by using distributed link regions, and using the N-type counter-doping implants at the bottom of trenches 115 and 125 to ensure a continuous N-type region on both sides of the doped sidewall regions 115-L, 115-R, 125-L, 125-R.

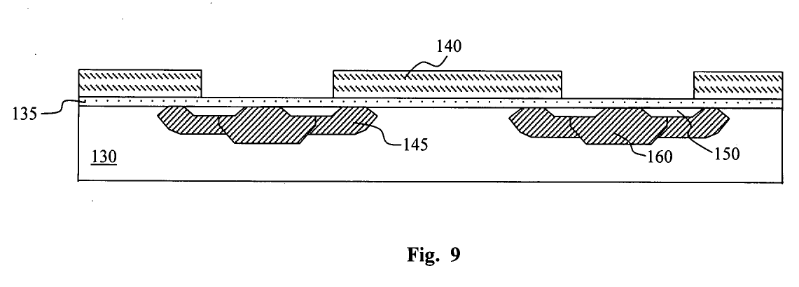

FIG. 9 is a cross sectional view to show different structures of a power device with different body contact and source contact formation. The structure as shown in FIG. 9 is manufactured with a specific source mask to form the source regions 150 that block the source dopant from entering into the central portions of the body regions 145. This embodiment demonstrates that the link region can be formed with different configurations and is not limited to the trench body contact as illustrated in above embodiments. Standard source contact formation based on a masked source process is also feasible for implementation with various device configurations disclosed in this invention.

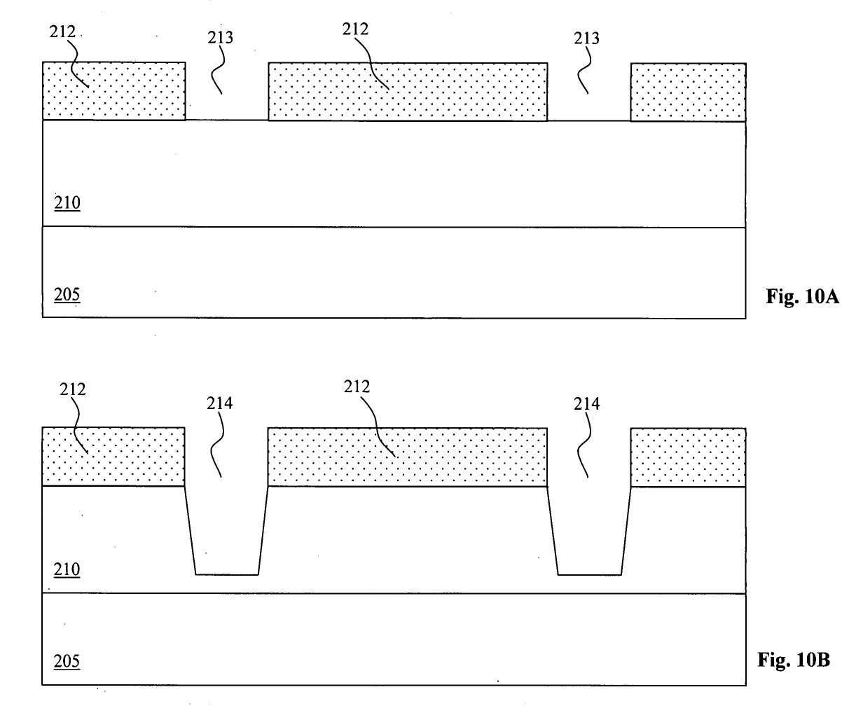

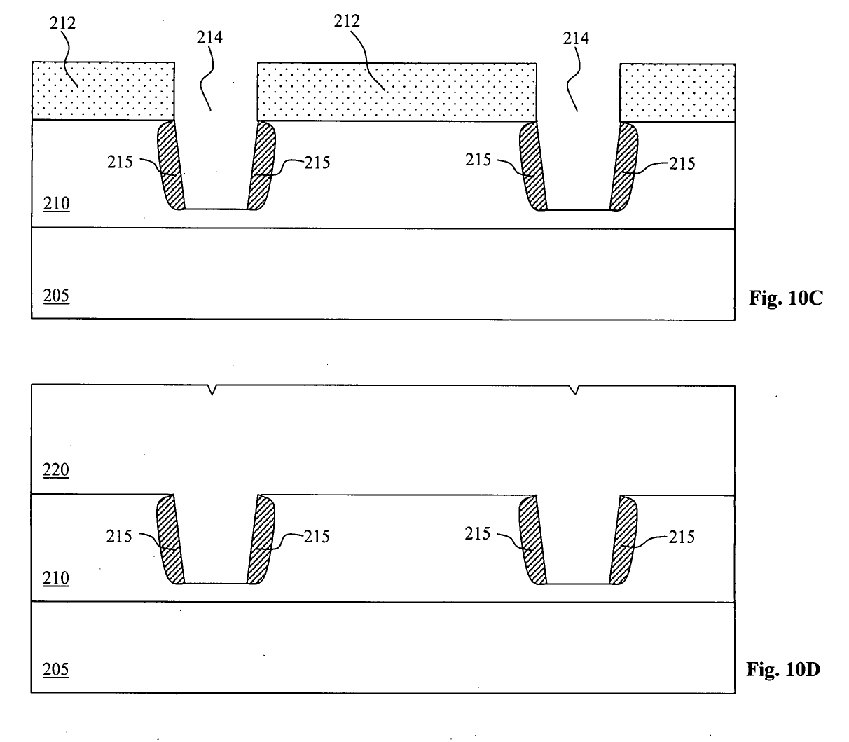

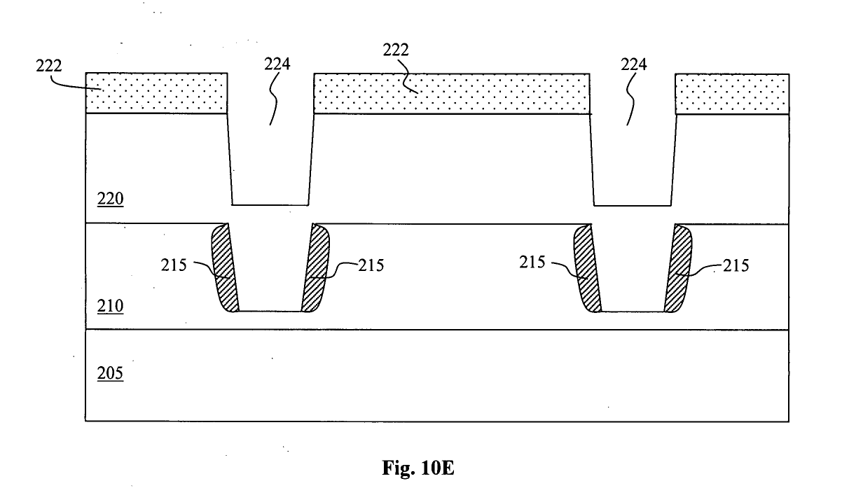

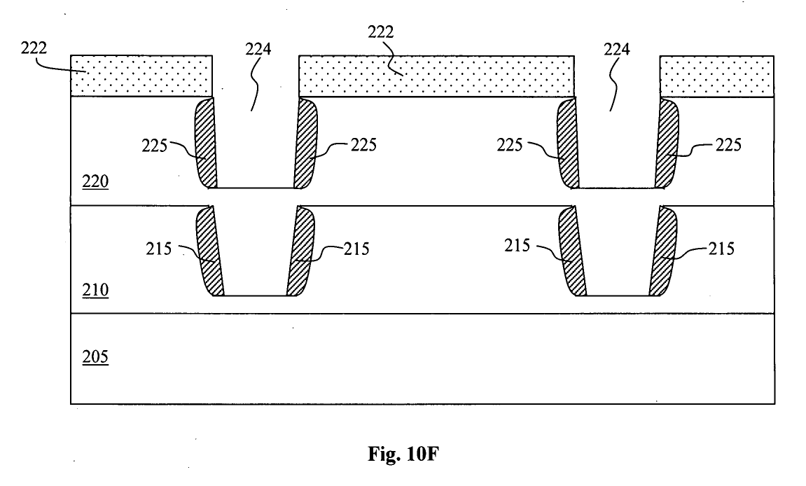

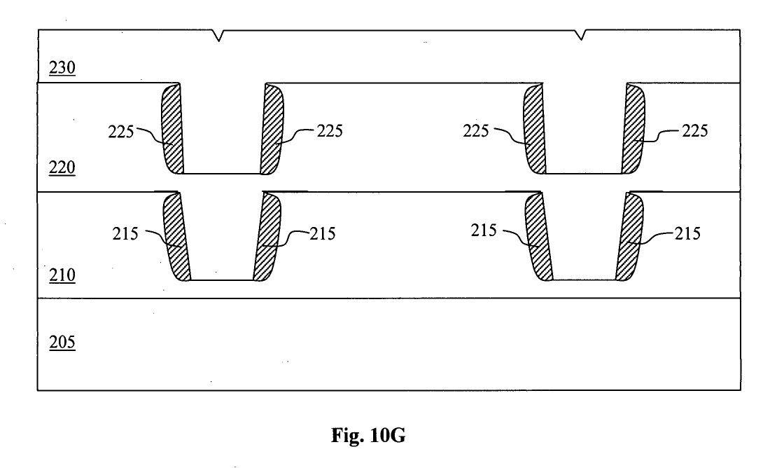

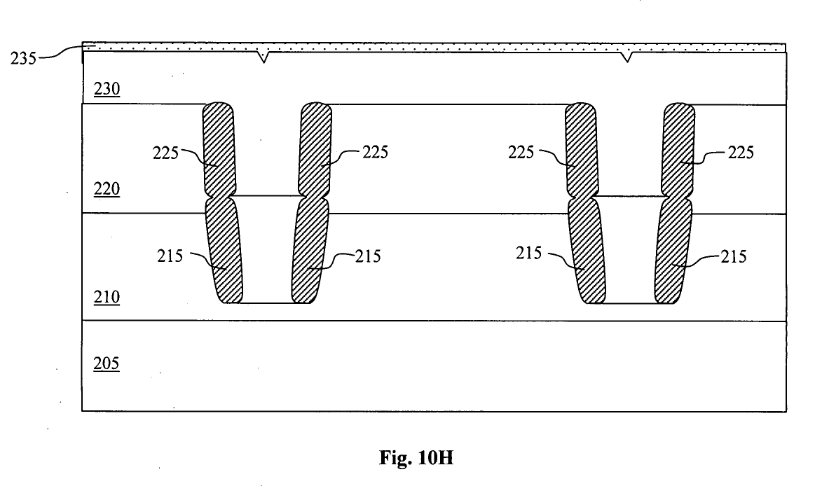

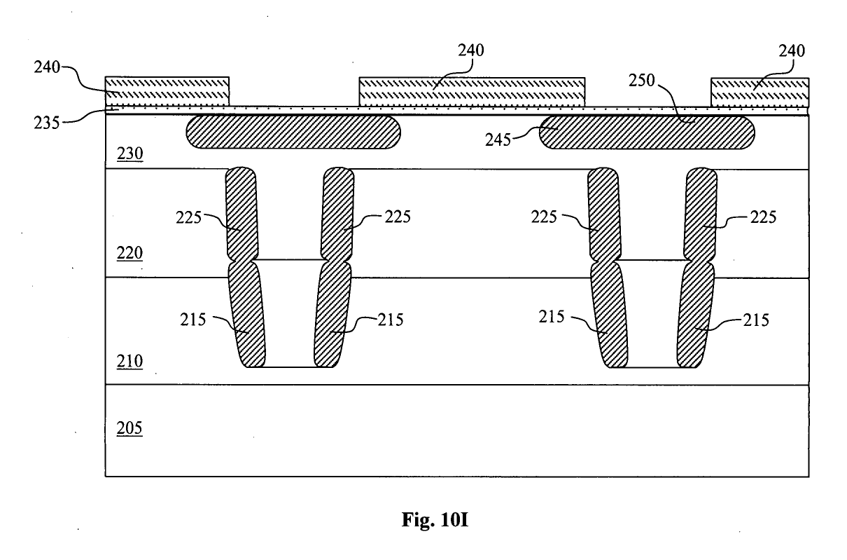

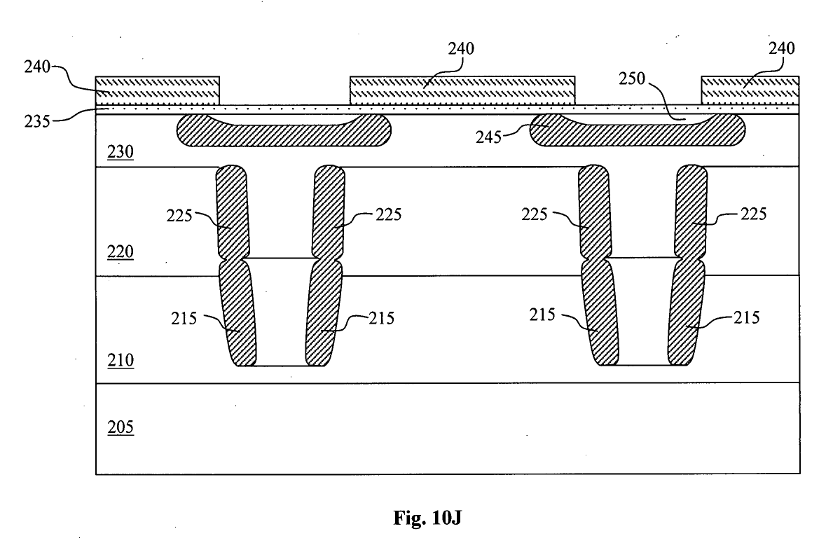

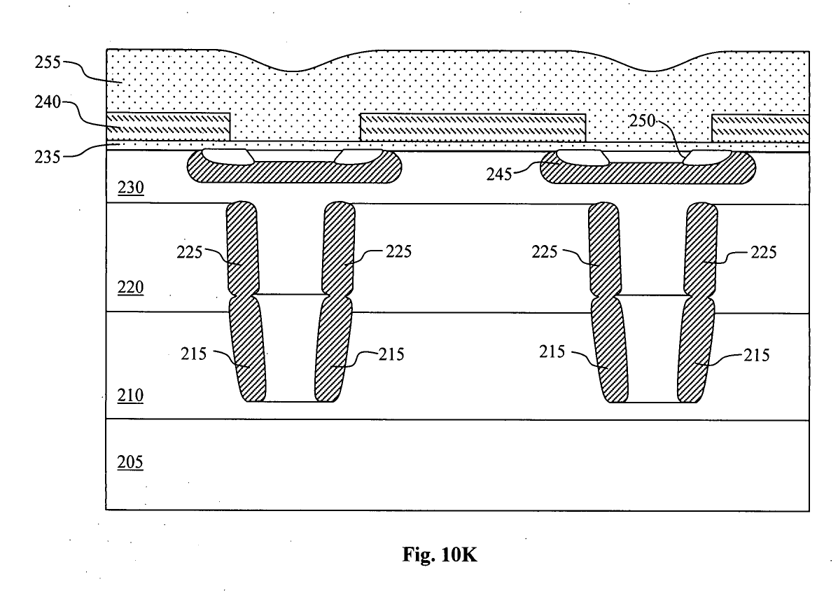

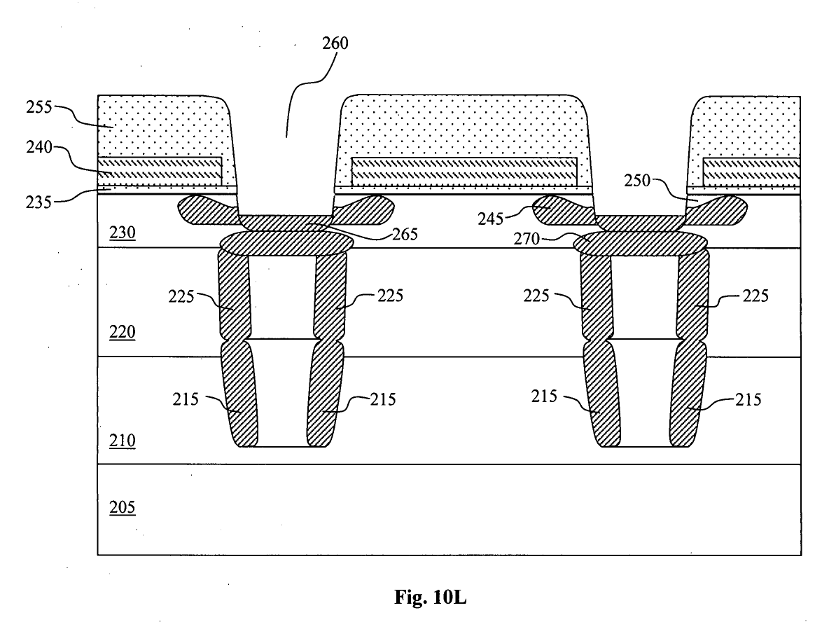

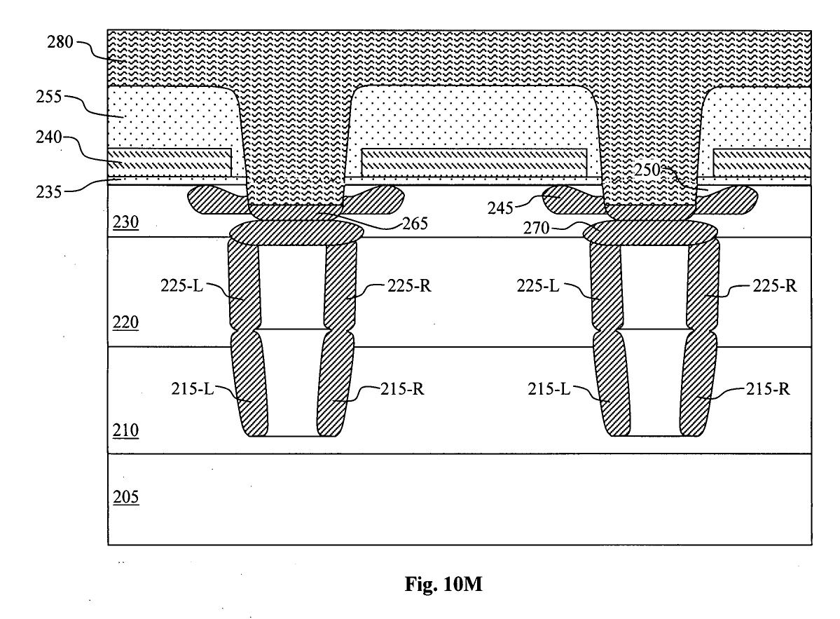

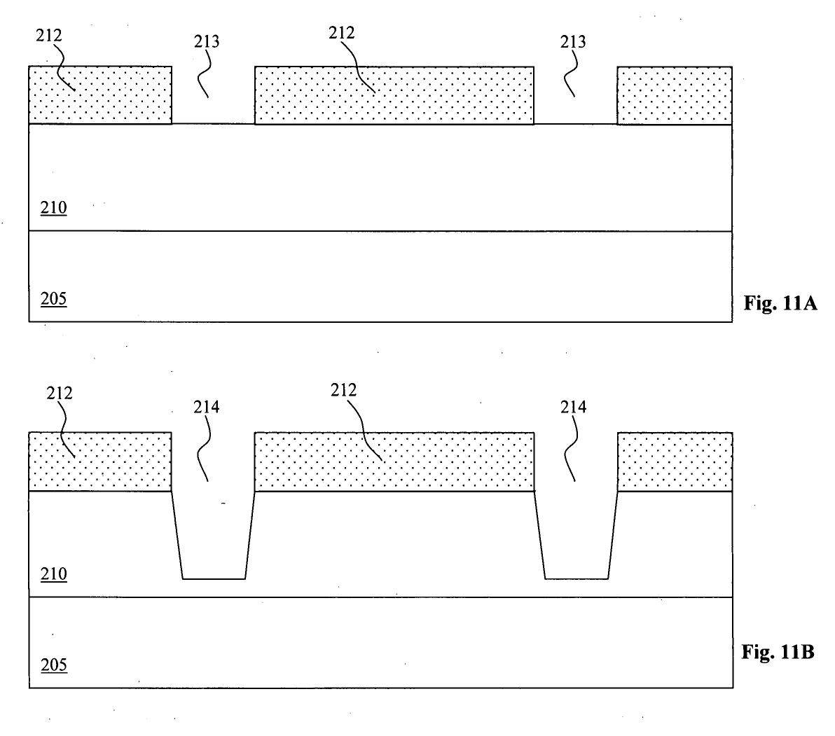

Referring to FIGS. 10A to 10M for a serial of side cross sectional views to illustrate the fabrication steps of a high voltage semiconductor power device as that shown in FIG. 2. In FIG. 10A shows a starting silicon substrate includes a N+ substrate 205 (typically doped with Antimony, Arsenic or Phosphorus, with a concentration >5E18/cm̂3 to minimize its resistivity) with a N-drift epitaxial layer 210 having a thickness ranging from 15 to 30 microns supported on the N+ substrate 205. The N-drift epitaxial layer 210 has a N-type dopant concentration ranging from 1E15 to 2.5E15/cm³ for the purpose to fabricate a high voltage power device with a breakdown voltage greater 600 volts. A hard mask oxide layer 212 is deposited or thermally grown with a thickness of 0.1 to 1.0 micrometer. Then a trench mask (not shown) is applied to carry out an oxide etch to open a plurality of trench etching windows 213. Depending on the type etcher and etch chemistries, photoresist only mask may also be used to pattern and open the trench as well instead of using the hard mask oxide layer 212 as shown. The trench opening may be in the 1 micron to 5 micron range for most applications.

In FIG. 10B, a silicon etch is carried out to open a plurality of trenches 214 with a depth of the trenches more than 20% of the thickness of the epitaxial layer 210. Preferably the depth of trench 214 is approximately 50 to 80% of the thickness of the epitaxial layer 210. In FIG. 10C, a trench sidewall implantation of boron ions by applying a tilt angle implantation is carried out to form sidewall P-doped regions 215 in the drift epitaxial layer 210. The implant dosage may be 1E12 to 3E13 cm̂−2 of boron ion flux at about 20Kev with a tile angle of about seven degrees (tilt range of 5 to 15 degrees may be used). Optionally, a perpendicular (zero tilt) phosphorus implant may be performed to counter the P-dopant in the epitaxial region below the bottom of the trench due to the boron sidewall implant. Then the photoresist is stripped. In FIG. 10D, the oxide layer 212 is removed followed by a process of growing an N-epitaxial layer 220 having a layer thickness of about 10 to 25 micrometers or equivalent to the trench depth of region 214. The N-type dopant concentration of the layer 220 is in a range of 1.0 to 2.5E15/cm3 that may be equal or higher than the dopant concentration of the N-type epitaxial layer 210 for a power device with a breakdown voltage of about 600 volts device.

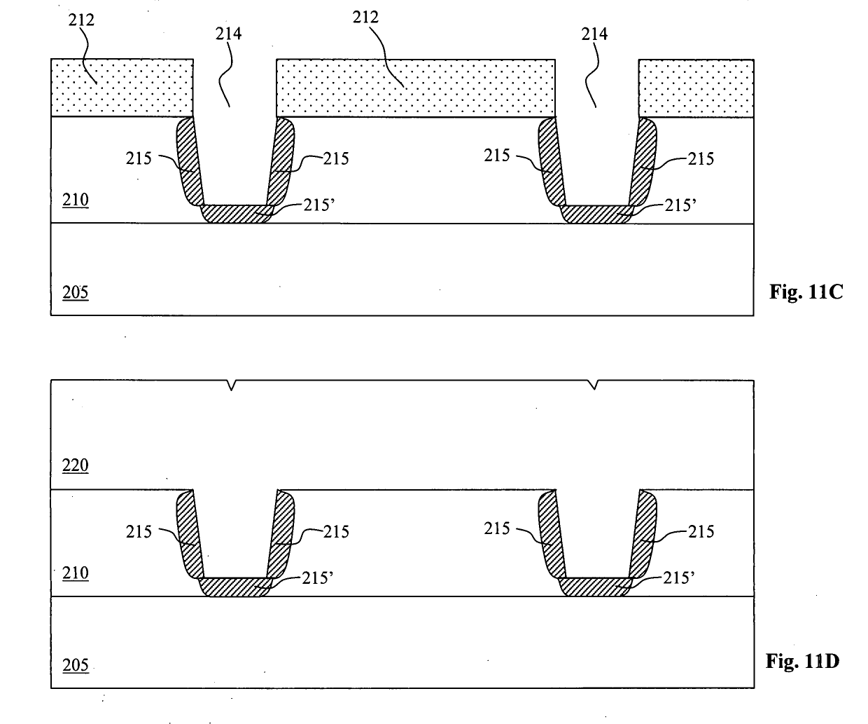

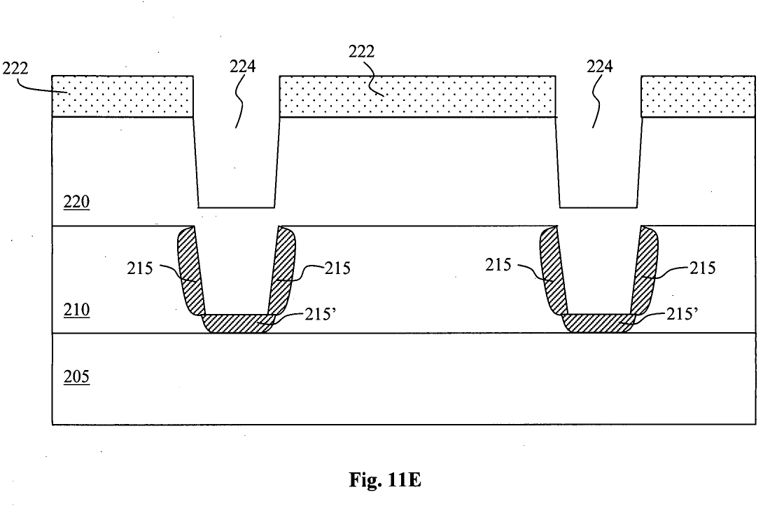

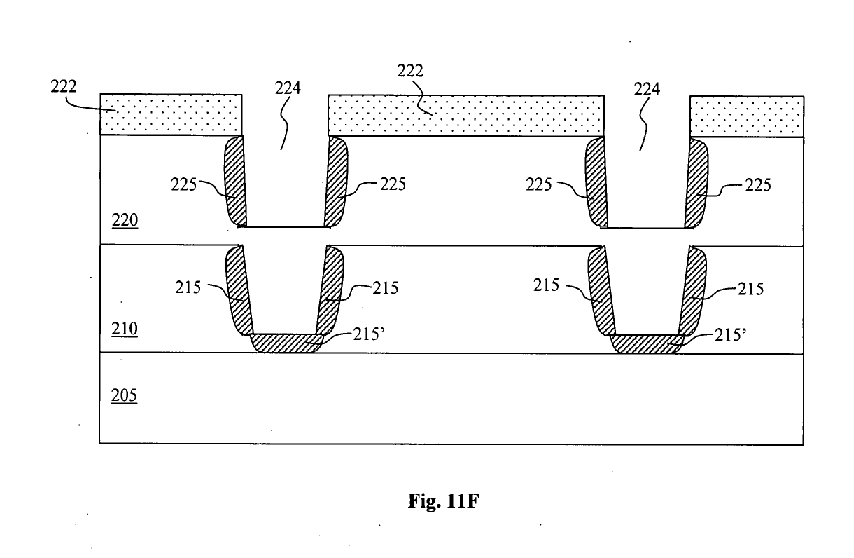

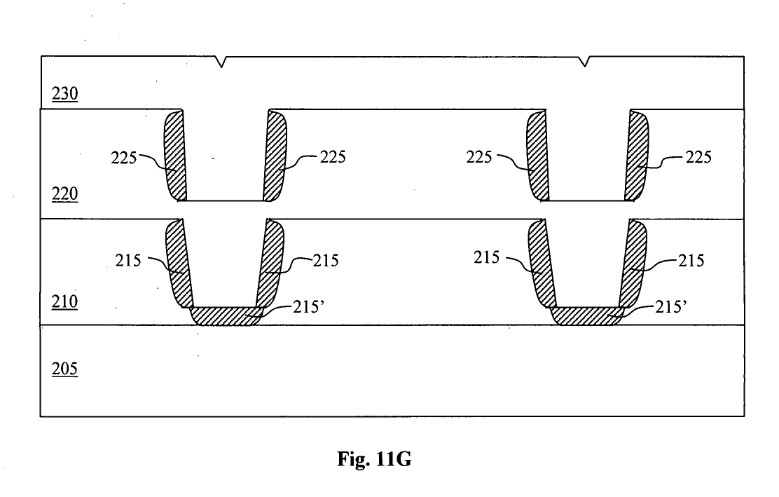

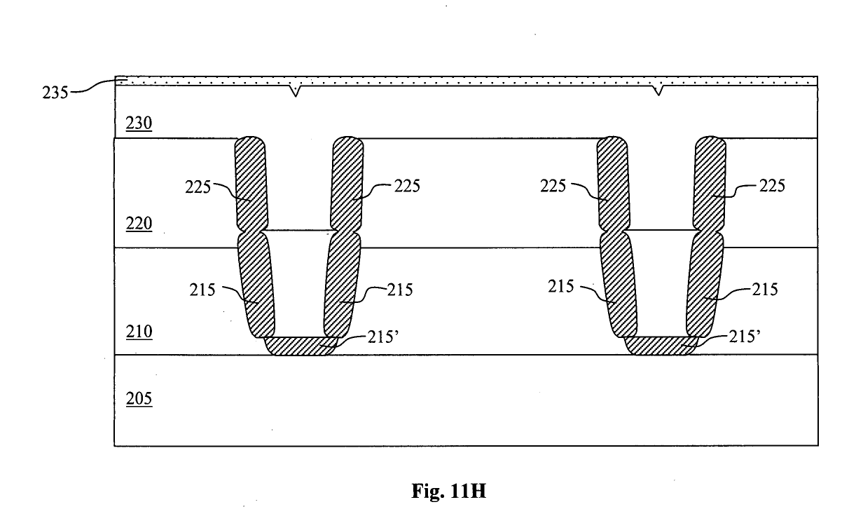

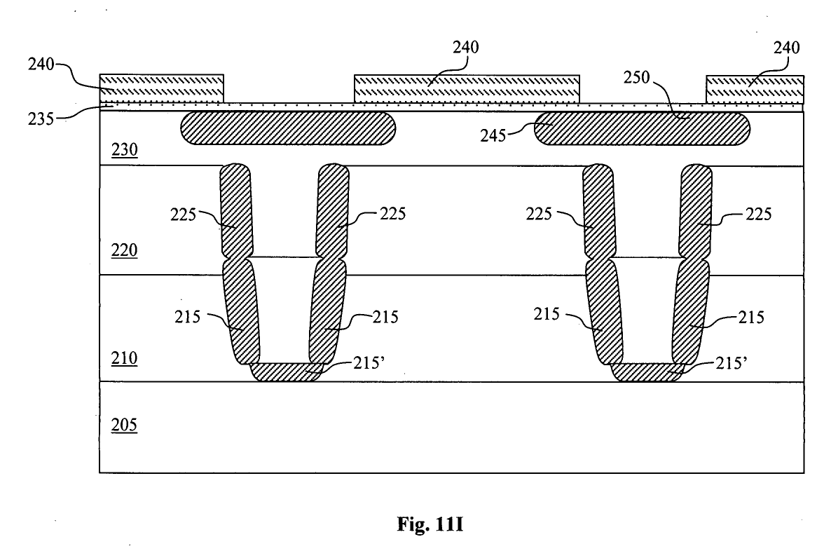

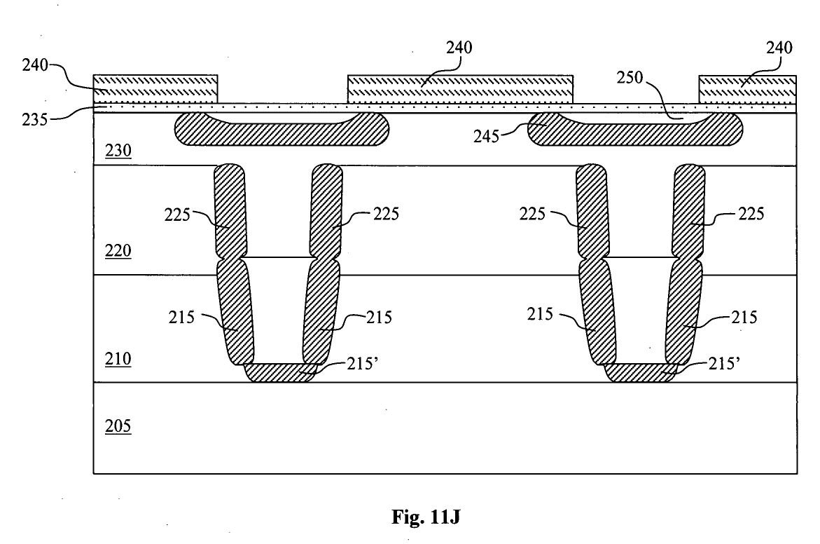

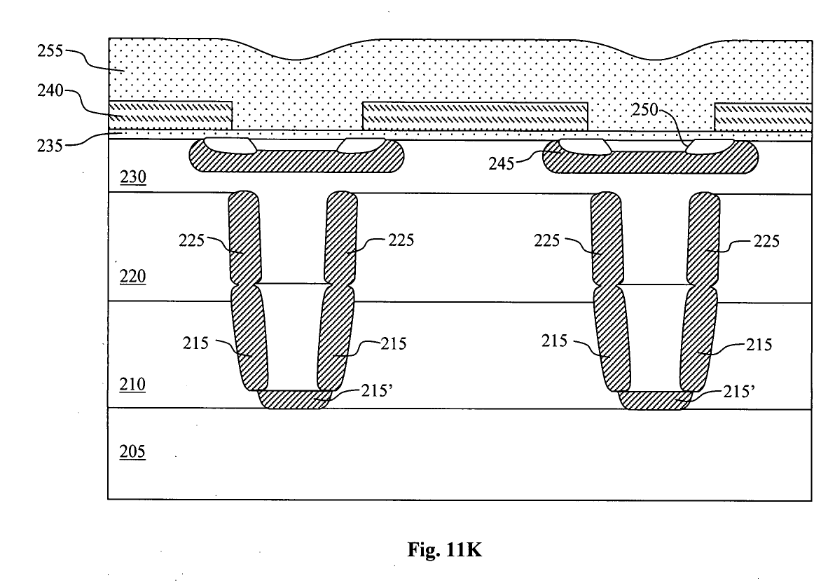

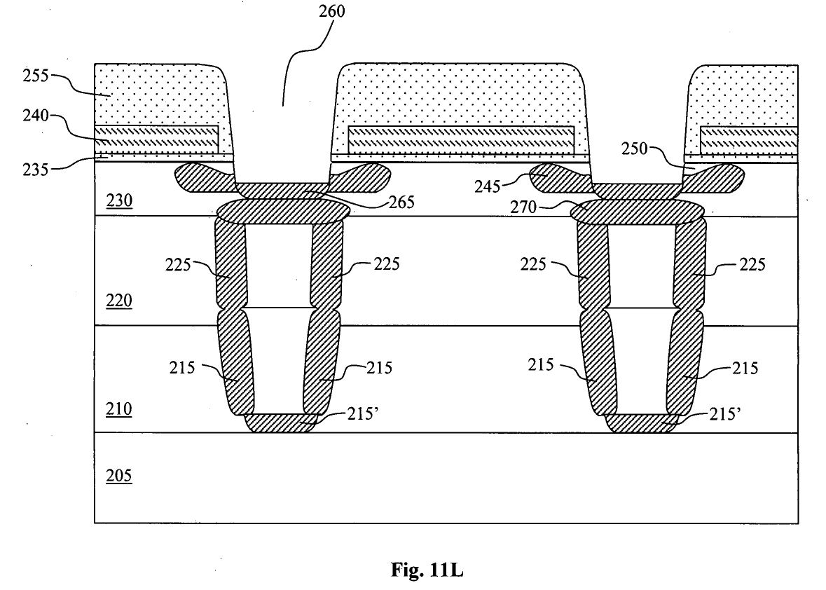

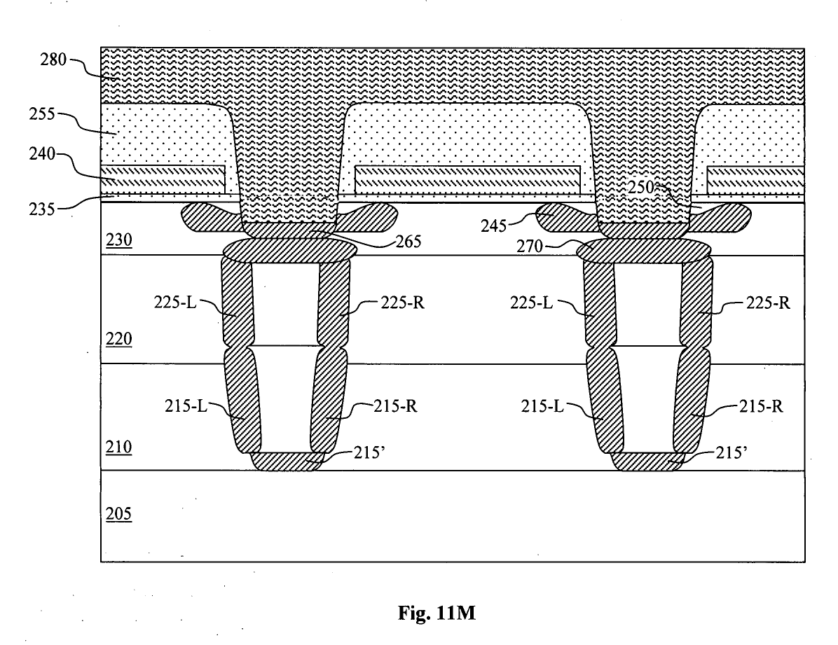

In FIG. 10E, an oxide layer 222 is deposited followed by applying a trench mask (not shown) having a critical dimension (CD) approximately in the range of one to five micrometers, i.e., 1.0 to 5.0μ, to carry out an oxide etch followed by a silicon etch to open a polarity of trenches 224 having a depth equivalent to the thickness of the epitaxial layer 220, e.g., 8 to 18 micrometers shallower than the first set of trenches 214. In one exemplary embodiment, the critical dimension of the trenches 224 is about 3 μm having a trench depth of about 12 μm. In FIG. 10F, trench sidewall implantation by implanting boron dopant ions with a tilt angle similar to the process shown in FIG. 11C is carried out to form sidewall implant regions 225 along the sidewalls of trenches 224. A perpendicular (zero-tilt) phosphorus implant is carried out to counter the boron dopant ions in the epitaxial drift region 220 beneath the trenches 224.

In FIG. 10G, the hard mask oxide layer 222 is removed followed by a process of growing a second N-type silicon epitaxial layer 230 with a thickness sufficient to fill the trenches 224. In an exemplary embodiment, the thickness of the second epitaxial layer 230 is about, or slightly larger than, half the width of the trenches 224. For example, the thickness of N-type epi 230 could be equal to half of the width of the trench 224, plus a ten to fifty percent thickness of the trenches 224. In another exemplary embodiment, the thickness of the second epitaxial layer is about 2.0 to 3.0 μm and having a N-type dopant concentration of 1.0-2.5E15/cm³ for a 600V device with low resistance. In FIG. 10H, a pad oxide 232 is formed on top of the second epitaxial layer 230. Optional processing steps such as nitride layer deposition, active area mask application, JFET surface implantation (N-type ion implant to reduce any parasitic JFET action which may take place between adjacent P-body regions, in order to minimize resistance), field oxidation, nitride and pad oxide removal and sacrificial oxide layer growth and removal may be performed (not shown). In FIG. 10J, a gate oxide layer 235 is formed followed by deposition and doping of a polysilicon layer 240. A gate mask (not shown) is applied to carry a polysilicon etch to pattern the gates 240. A body mask (not shown) is applied as an option followed by an etch process to form the floating guard ring termination is necessary). A body implant is performed followed by body diffusion to form the body regions 245.

In FIG. 10J, a source implant is carried out. In an exemplary embodiment, the source dopant of arsenic ions with implant ion flux of 4E15 having implant energy of 70 Kev is applied followed by an anneal operation to form the source region 250.

In FIG. 10K, a dielectric deposition of LTO and BPSG layer 255 is carried out followed by a BPSG reflow and densification process. In FIG. 10L, a source and body contact mask (not shown) that preferably as photoresist with thickness greater than 1.5 μm, is applied to etch through the dielectric layer 255. A silicon etch is performed to remove the gate oxide layer 235 and the central portion of the source region 250 to open the body contact widows 260 which will also act as source contact, along the sidewalls. A shallow high dose boron or BF2 implant with implant dosage of 2E15 at an implant-energy less than 65 Kev is carried out to form the P+ contact regions 265. A deep boron implant (or a series of deeper boron implants) with dosage greater than 4E13 and implant energy greater than 100 Kev is applied to form the P-link regions between the surface body contact regions 245 and the buried P-columns 215 and 225. In FIG. 10M, a metal layer 280 is deposited and a metal mask (not shown) is applied to pattern the metal layer to form the source body contact and gate pad (not shown). The processes of fabricating the semiconductor power device is completed by passivation layer deposition, passivation bond pad mask application and etch and an alloy process (not shown).

Referring to FIGS. 11A to 11M for a serial of side cross sectional views to illustrate the fabrication steps to manufacture an alternate high voltage semiconductor power device as that shown in FIG. 3. In FIG. 11A shows a starting silicon substrate includes a N+ substrate 205 with a N-drift epitaxial layer 210 having a thickness ranging from 20 to 30 microns supported on the N+ substrate 205. The N-drift epitaxial layer 210 has a N-type dopant concentration ranging from 1E15 to 2.5E15/cm³ for the purpose to fabricate a high voltage power device with a breakdown voltage greater 600 volts with low resistance. A hard mask oxide layer 212 is deposited or thermally grown with a thickness of 0.1 to 1.0 micrometer. Then a trench mask (not shown, CD as described above) is applied to carry out an oxide etch to open a plurality of trench etching windows 213. Depending on the type etcher and etch chemistries, photoresist only mask may also be used to pattern and open the trench as well instead of using the hard mask oxide layer 212 as shown.

In FIG. 11B, a silicon etch is carried out to open a plurality of trenches 214 with a depth of the trenches more than 20% of the thickness of the epitaxial layer 210. Preferably the depth of the trenches 214 is approximately 50 to 80% of the thickness of the epitaxial layer 210. In FIG. 11C, a trench sidewall implantation of boron ions by applying a tilt angle implantation is carried out to form sidewall P-doped regions 215 in the drift epitaxial layer 210. The implant dosage may be 1E12 to 2E13 of boron ion flux at about 20Kev with a tile angle of about seven degrees. The N-type trench bottom compensating implant is then skipped, which leaves a P-doped region 215′ at the bottom of the trench 214. Then the photoresist is stripped. In FIG. 11D, the oxide layer 212 is removed followed by a process of growing an N-epitaxial layer 220 having a layer thickness of about 10 to 25 micrometers that is equivalent to the trench depth. The dopant concentration of the layer 220 is in a range of 1.0 to 2.5E15/cm3 that may be equal or higher than the dopant concentration of the epitaxial layer 210 for a power device with a breakdown voltage of about 600 volts device and low resistance.

In FIG. 11E, an oxide layer 222 is deposited followed by applying a trench mask (not shown) having a critical dimension (CD) approximately in the range of one to five micrometers, i.e., 1.0 to 5.0μ, to carry out an oxide etch followed by a silicon etch to open a polarity of trenches 224 having a depth equivalent to the thickness of the epitaxial layer 220, e.g., 8 to 18 micrometers shallower than the first set of trenches 214. In one exemplary embodiment, the critical dimension of the trenches 224 is about 3 μm having a trench depth of about 12 μm. In FIG. 11F, trench sidewall implantation by implanting boron dopant ions with a tilt angle similar to the process shown in FIG. 11C is carried out to form sidewall implant regions 225 along the sidewalls of trenches 224. A perpendicular phosphorus implant is carried out to counter the boron dopant ions in the epitaxial drift region 220 beneath the trenches 224.

In FIG. 11G, the hard mask oxide layer 222 is removed followed by a process of growing a second silicon epitaxial layer 230 with a thickness sufficient to fill the trenches 224. In an exemplary embodiment, the thickness of the second epitaxial layer 230 is about half the width of the trenches 224 plus a ten to fifty percents thickness of the trenches 224. In another exemplary embodiment, the thickness of the second epitaxial layer is about 2.0 to 3.0 μm and having a N-type dopant concentration of 1.0-2.5E15/cm³. In FIG. 11H, a pad oxide 232 is formed on top of the second epitaxial layer 230. Optional processing steps such as nitride layer deposition, active area mask application, JFET surface implantation, field oxidation, nitride and pad oxide removal and sacrificial oxide layer growth and removal may be performed (not shown). In FIG. 11I, a gate oxide layer 235 is formed followed by deposition and doping of a polysilicon layer 240. A gate mask (not shown) is applied to carry a polysilicon etch to pattern the gates 240. A body mask (not shown) is applied as an option followed by an etch process to form the floating guard ring termination is necessary). A body implant is performed followed by body diffusion to form the body regions 245.

In FIG. 11J, a source implant is carried out. In an exemplary embodiment, the source dopant of arsenic ions with implant ion flux of 4E15 having implant energy of 70 Kev is applied followed by an anneal operation to form the source region 250. In FIG. 11K, a blanket body contact implant is carried out to form body/source contact dopant regions (not shown). A dielectric deposition of LTO and BPSG layer 255 is carried out followed by a BPSG reflow and densification process. In FIG. 11L, a source and body contact mask (not shown) that preferably as photoresist with thickness greater than 2 μm, is applied to etch through the dielectric layer 255. A silicon etch is performed to remove the gate oxide layer 235 and the central portion of the source region 250 to open the source/body contact widows 260. A shallow high dose boron or BF2 implant with implant dosage of 2E15 at an implant-energy less than 65 Kev is carried out to form the P+ contact regions 265. A deep boron implant with dosage greater than 4E13 and implant energy greater than 100 Kev is applied to form the P-link regions between the surface body regions 245 and the buried P-columns 215 and 225. In FIG. 11M, a metal layer 280 is deposited and a metal mask (not shown) is applied to pattern the metal layer to form the source body contact and gate pad (not shown). The processes of fabricating the semiconductor power device is completed by passivation layer deposition, passivation bond pad mask application and etch and an alloy process (not shown).

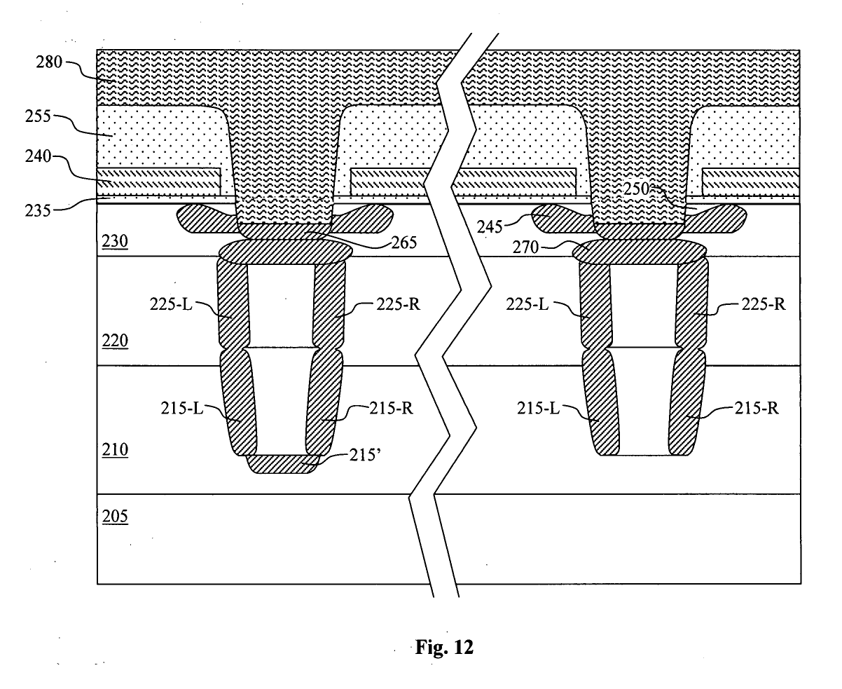

FIG. 12 shows two alternate processes according to FIGS. 10C and 11C. This embodiment uses a thicker N-drift region 210, or a shallower first trench 214, or a combination of both. Benefits of a shallower trench 214 for example are reduced processing time. On the left hand side of FIG. 12, a bottom P-type region 215′ is formed as a result of skipping any N-type zero-tilt compensating implant. On the right hand side of FIG. 11, a perpendicular phosphorus “compensating” implant is carried out through the trench bottom to compensate to dopant concentration in the drift region below the trench that is at a distance from the bottom N+ substrate 205.

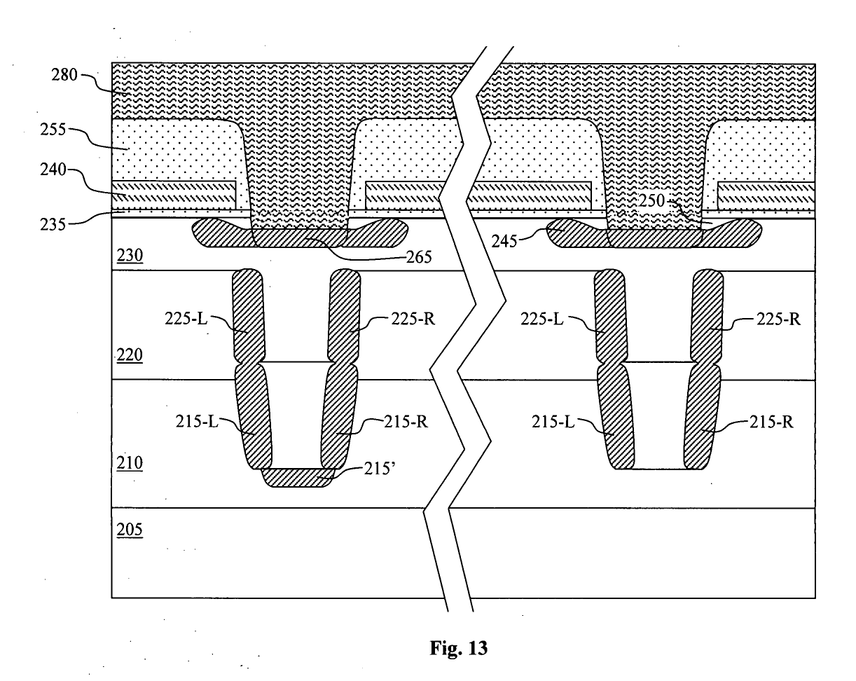

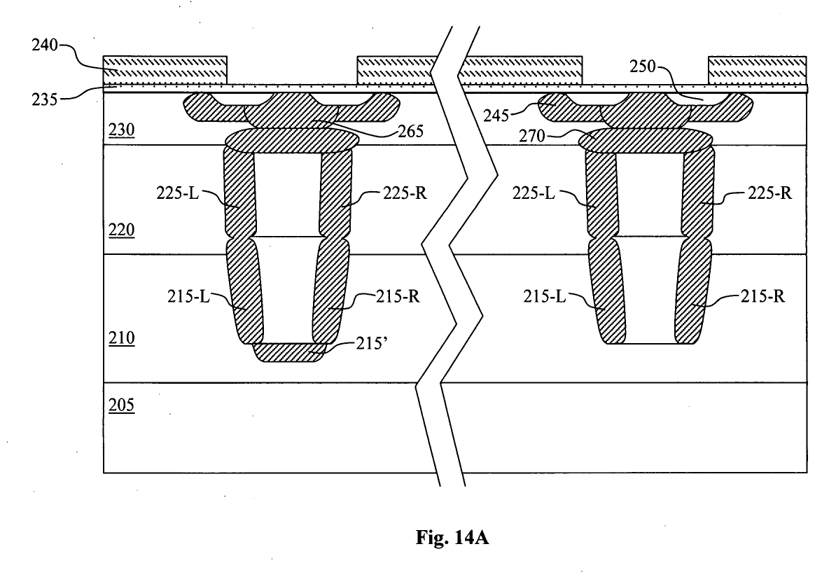

FIG. 13 shows a floating island version of the structure shown in FIG. 12.

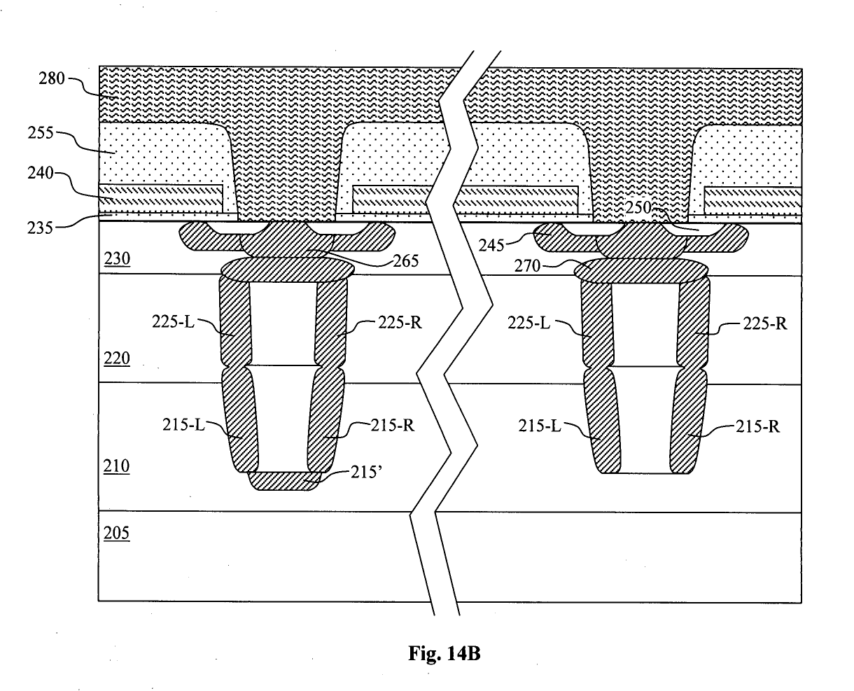

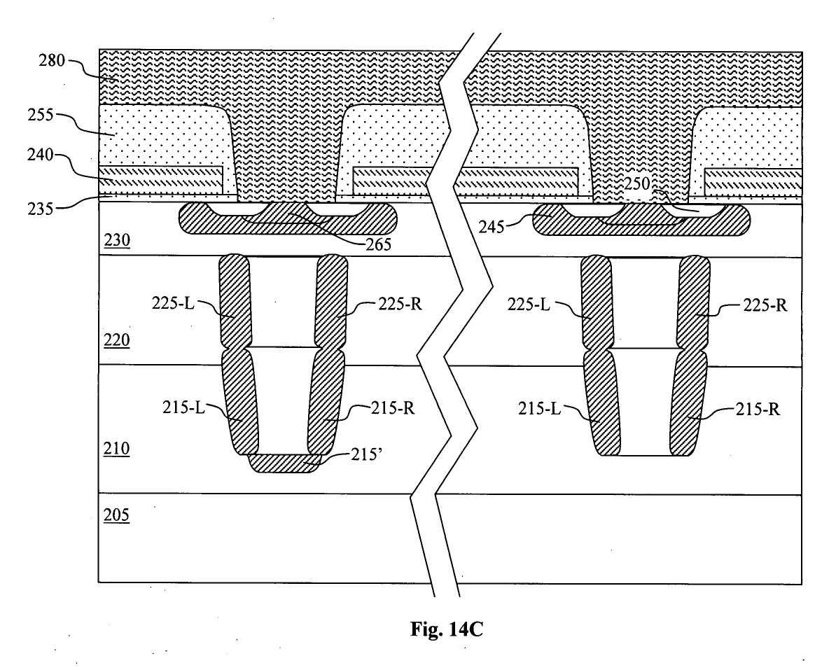

FIG. 14 shows a structure similar to that of FIG. 12, but with a non-trenched body and source contact. FIGS. 14A to 14C are cross sectional views for illustrating processing steps according to method 7 and method 8 to manufacture the power device of this invention. In FIG. 14A, a source mask (not shown) is applied to in forming the source regions 250 to block the source dopant ions from entering into the center portion body regions 245.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

I claim:

1. A method for manufacturing semiconductor power device on a semiconductor substrate supporting a drift region composed of an epitaxial layer thereon, the method comprising:
opening a plurality of lower trenches in said drift region followed by doping sidewalls of said lower trenches to form a plurality of lower doped-sidewall columns along said sidewalls of said lower trenches; and
forming a first epitaxial layer on top of said drift region to fill at least part of said lower trenches followed by opening a plurality of upper trenches substantially on top of each of said lower trenches and doping sidewalls of said upper trenches to form a plurality of upper doped-sidewall columns; and
filling and covering said upper trenches with a second epitaxial layer on top of said first epitaxial layer followed by applying a power device manufacturing step for extending and connecting said lower and upper doped sidewall columns into a plurality of combined doped sidewall columns in said semiconductor substrate.

2. The method of claim 1 wherein:
said step of opening said lower trenches further comprising a step of opening said trenches having a depth of more than 20% of a thickness of said drift region and said step of opening said upper trenches further comprising a step of opening said upper trenches having a depth approximate a thickness of said first epitaxial layer.

3. The method of claim 1 wherein:
said step of doping said sidewalls of said lower trenches and said upper trenches further comprising a step of applying a tilt implantation with a tilt angle of approximately five to fifteen degrees relative to a direction along a direction of said sidewalls of said upper and lower trenches.

4. The method of claim 1 further comprising:
applying a zero-tilt perpendicular implantation to dope an area below a bottom of said lower trenches with a dopant having an opposite conductivity type with dopant applied in doping said sidewalls of said lower trenches to compensate an area below said trench bottom of said lower trenches with counter-dopant ions.

5. The method of claim 1 wherein:
said step of forming a first epitaxial layer to fill at least part of said lower trenches further comprising a step of forming said first epitaxial layer having a dopant concentration equal to or higher than a dopant concentration of said drift region.

6. The method of claim 1 wherein:
said step of forming a first epitaxial layer to fill at least part of said lower trenches further comprising a step of forming said first epitaxial layer having a thickness of approximately five to twenty five micrometers.

7. The method of claim 6 wherein:
said step of forming said upper trenches further comprising a step of opening said upper trenches having a depth of approximately five to twenty-five micrometers.

8. The method of claim 1 further comprising:
applying a zero-tilt perpendicular implantation to dope an area below a bottom of said upper trenches with a dopant having a opposite conductivity type with dopant applied in doping said sidewalls of said upper trenches to compensate an area below said trench bottom of said upper trenches with counter-dopant ions.

9. The method of claim 1 wherein:
said step of filling and covering said upper trenches with a second epitaxial layer further comprising a step of forming said second epitaxial layer having a thickness of approximately one to four micrometers above a top surface of said upper trenches.

10. The method of claim 1 wherein:
said step of applying a power device manufacturing step further comprising a step of forming a gate on top of said second epitaxial layer and forming a body region and a source region in said second epitaxial layer followed by forming a source and body contact through an insulation layer covering said semiconductor device; and
forming a doped buried linker region for electrically linking said combined sidewall-doped columns to said body region.

11. The method of claim 1 further comprising:
applying a zero-tilt perpendicular implantation to dope a doped trench bottom region in an area below a bottom of said lower trenches with a dopant having a same conductivity type with dopant applied in doping said sidewalls of said lower trenches.

12. The method of claim 11 wherein:
said step of implanting said doped trench bottom region in an area below a bottom of said lower trenches further comprising a step of implanting said doped trench bottom region touching a lower substrate layer below said drift region.

13. The method of claim 11 wherein:
said step of implanting said doped trench bottom region in an area below a bottom of said lower trenches further includes a step of implanting said doped trench bottom region at a distance above a lower substrate layer below said drift region.

14. The method of claim 1 wherein:
said step of applying a power device manufacturing step further comprising a step of forming a metal oxide field effect transistor (MOSFET) device in and supported by said semiconductor substrate supporting said first and second epitaxial layer with said plurality of combined doped sidewall columns disposed in said drift region and said first epitaxial layer; and
forming a doped buried linker region for electrically linking said combined sidewall-doped columns to a body region of said MOSFET device.

15. The method of claim 1 wherein:
said step of implanting said plurality of combined doped sidewall columns in said semiconductor substrate further comprising a step of implanting said plurality of combined doped sidewall columns as P-doped sidewall columns in a N-type substrate.

16. The method of claim 1 wherein:
said step of implanting said plurality of combined doped sidewall columns in said semiconductor substrate further comprising a step of implanting said plurality of combined doped sidewall columns as N-doped sidewall columns in a P-type substrate.

17. A method for manufacturing semiconductor power device on a semiconductor substrate supporting a drift region composed of an epitaxial layer thereon, the method comprising:
forming a super-junction structure by first opening a plurality of lower trenches in said drift region followed by doping sidewalls of said lower trenches to form a plurality of lower doped-sidewall columns along said sidewalls of said lower trenches; and
repeating a process of filling said plurality of trenches with a covering epitaxial layer on top of lower epitaxial layer and opening a plurality of upper trenches substantially on top of each of said lower trenches and doping sidewalls of said upper trenches to form a plurality of upper doped-sidewall columns whereby multiple epitaxial layers filling multiple layers of trenches opened therein implanted with doped sidewall dope columns are formed in said multiple epitaxial layers.

18. A semiconductor power device disposed on a semiconductor substrate supporting an epitaxial layer as a drift region composed of an epitaxial layer thereon, comprising:
a super-junction structure includes a plurality of doped sidewall columns disposed in a multiple of epitaxial layers wherein said epitaxial layers having a plurality of trenches opened and filled therein with said epitaxial layer with said doped sidewall columns disposed along sidewalls of said trenches disposed in said multiple of epitaxial layers.

19. The semiconductor power device of claim 18 further comprising:
a bottom doped region disposed in said drift region below and linking between two of said doped sidewall columns.

20. The semiconductor power device of claim 18 further comprising:
a buried linker region disposed in said drift region above and linking between two of said doped sidewall columns.

21. The semiconductor power device of claim 20 wherein:
Said buried linker region further extending upward to a heavy body region for electrically linking said doped sidewall columns to an electrical terminal of said semiconductor power device.

22. The semiconductor power device of claim 21 wherein:
said heavy body region disposed in a bottom of trench filled with conductive material for forming an ohmic contact.

23. The semiconductor power device of claim 20 wherein:
said heavy body region extending to a top surface of epitaxial region for ohmic contacting with an overlaying conductive layer.

24. The semiconductor power device of claim 20 wherein:
said buried linker region forming a stripe finger under said heavy body region.

25. The semiconductor power device of claim 20 wherein:
said buried linker regions distributed along the locations of contact openings.
